(19) United States
(12) Patent Application Publication
(10) Pub. No.: US 2026/0245615 A1
(43) Pub. Date: Aug. 20, 2026

(54) READ-ONCE MEMORY CIRCUIT

(71) Applicant: Apple Inc., Cupertino, CA (US)

(72) Inventor: Martin R. FURUHJELM, Scotts Valley, CA (US)

(21) Appl. No.: 19/543,616

(22) Filed: Feb. 18, 2026

Related U.S. Application Data
(60) Provisional application No. 63/760,850, filed on Feb. 20, 2025.

(51) Int. Cl. G11C 11/4096; G11C 11/4091

(52) U.S. Cl. CPC G11C 11/4096; G11C 11/4091

(57) ABSTRACT

Various embodiments of a read-once memory are disclosed. A memory circuit includes a control circuit and multiple memory cells that store respective bits of data. The control circuit, upon receiving a read access command may check an operating mode of the memory circuit. In cases where the operating mode is a destructive read mode, the control circuit may sense data from a subset of the multiple memory cells based on an address included in the read access command. The control circuit may also, upon completion of the sensing, abort a restore operation that restores the sensed data back into the subset of the multiple memory cells.

### CROSS-REFERENCE TO RELATED APPLICATIONS

The present application claims the benefit of U.S. Provisional Application No. 63/760,850, entitled “READ-ONCE MEMORY CIRCUIT,” filed Feb. 20, 2025, the content of which is incorporated by reference herein in its entirety for all purposes.

### FIELD

This disclosure relates to the field of integrated circuit implementation and, more particularly, to the implementation of memory circuits.

### BACKGROUND

Modern computer systems include multiple circuit blocks designed to perform various functions. For example, such circuit blocks may include processors or processor cores configured to execute software or program instructions. Additionally, the circuit blocks may include a variety of memory circuits that store software or program instructions as well as data to be processed.

Memory circuits in a computer system may be used in a variety of ways. For example, small memory circuits with fast access times may be used as cache memory circuits storing frequently used program instructions or data. Alternatively, large memory circuits with longer access times may be used as main memory for the computer system.

The memory circuits in a computer system may be implemented using a variety of storage cells (also referred to as memory cells). Some memory circuits use static storage cells that are able to store data as long as they are connected to a power supply, while other memory circuits employ dynamic memory cells that rely on charge stored in a capacitor to store data. Such dynamic memory cells must be periodically refreshed to maintain a desired level of charge in the capacitors. Other memory circuits can employ floating-gates or other structures to store data even when the memory circuits are disconnected from a power supply.

### BRIEF DESCRIPTION OF THE DRAWINGS

FIG. 1 is a block diagram depicting an embodiment of a memory subsystem for a computer system.

FIG. 2 is a block diagram depicting an embodiment of a read-once memory circuit that includes multiple banks.

FIG. 3 is a block diagram depicting an embodiment of a sub-array circuit for a read-once memory circuit.

FIG. 4 is a block diagram depicting an embodiment of a sense amplifier circuit.

FIG. 5 is a chart depicting an embodiment of read-once memory commands.

FIG. 6 is a flow diagram depicting an embodiment of a method for operating a read-once memory circuit.

FIG. 7 is a flow diagram depicting an embodiment of a method for refreshing a read-once memory circuit.

FIG. 8 is a block diagram of an embodiment of a device that may include analog circuits.

FIG. 9 is a block diagram of various embodiments of computer systems that may include analog circuits.

FIG. 10 illustrates an example of a non-transitory computer-readable storage medium that stores circuit design information.

### DETAILED DESCRIPTION

Computer systems employ a variety of memory circuits for different uses. In some cases, e.g., main memory, dynamic random-access memory (DRAM) circuits are used to store program or software instructions as well as data. Such data can be operands for calculations, image data, video data, audio data, and the like.

A memory cell for a DRAM circuit can be implemented using a transistor and a capacitor. During a read access, the transistor is activated, coupling the capacitor to a bit line. Charge, or a lack thereof, in the capacitor results in a change in the voltage level of the bit line that can be sensed to determine a corresponding logic value for the data stored in the memory cell. Since the charge in the capacitor has been disturbed when it is coupled to the bit line, the charge has to be restored in order to maintain the stored data. The process of resetting the charge in the capacitor of a memory cell is referred to as a restore operation, which consume additional power on top of the sensing operation.

Some computer systems are implemented using a von Neumann architecture where program instructions and data share a common memory. When executing a loop, such a computer system would perform multiple reads to the common memory to retrieve the instructions from the loop. The repeated read operations can consume considerable power. In some cases, different memory cache architectures can be employed to locally store such instructions so the computer system does not have to continue to access the common memory during the execution of the loop.

Other processor architectures, e.g., the graphics processor unit (GPU) architecture, can implement sequences of instructions using logic circuits. For example, a sequence to perform floating-point multiplication may be implemented completely using logic circuits. In this case, only data, e.g., pixel data, is stored in memory since the instructions are implemented in hardware.

In some applications, e.g., machine-learning or artificial intelligence, a computer system may perform a large number of matrix multiplication operations. GPUs or tensor processing units (TPUs) can be well suited to perform such matrix multiplication operations. In many cases, such matrix multiplication operations take the form of an n×n matrix multiplied by a vector, where n is a positive integer. The result of such operations may be stored into memory for future use, or it may be added to a previous result already stored in memory. A large amount of memory may be used to perform such calculations as the matrices can be large, often including billions of elements.

In such matrix multiplications, the multiplier and the multiplicand are commonly not used again, so once used, the values can be discarded. When dynamic memory circuits are used, the single-use values are restored into corresponding memory cells once the values have been sensed, resulting in a substantial power consumption to maintain data that is no longer needed.

The embodiments illustrated in the drawings and described below provide techniques for selectively making a read access to a dynamic memory either destructive or non-destructive. By designating a read access for single-use data as destructive, the single-use data is not restored into memory cells thereby saving the power associated with the restore operation.

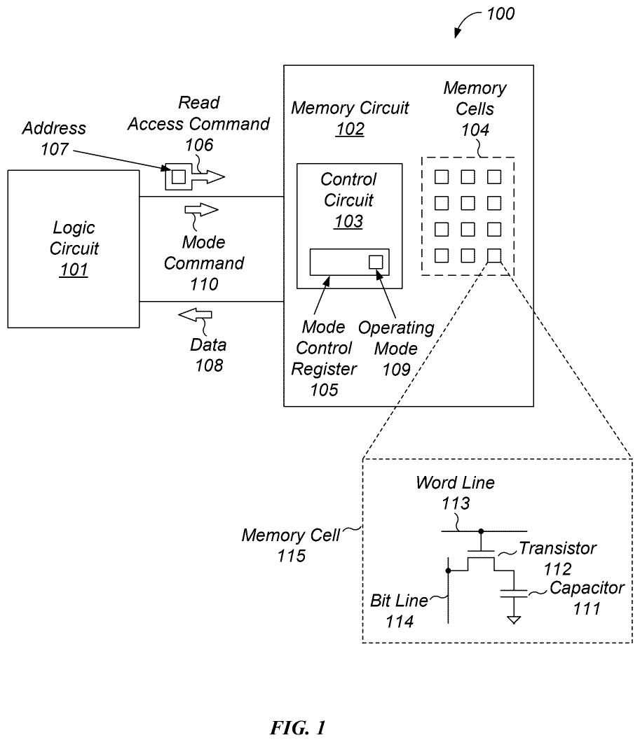

A block diagram of a memory subsystem is depicted in FIG. 1. As illustrated, memory subsystem 100 includes logic circuit 101 and memory circuit 102. Although a single memory circuit is depicted in the embodiment of FIG. 1, in other embodiments, any suitable number of memory circuits may be employed.

Logic circuit 101 is configured to send read access command 106 to memory circuit 102, and receive data 108 from memory circuit 102 in response to memory circuit 102 executing read access command 106. In various embodiments, read access command 106 includes address 107. Although logic circuit 101 is depicted as sending a single read access command, in other embodiments, logic circuit 101 may send any suitable number of read access commands with corresponding addresses. Moreover, logic circuit 101 may send other types of commands, e.g., write commands, to memory circuit 102.

Logic circuit 101 may include a processor circuit, one or more processor cores, a microcontroller, or any other suitable processing circuits. In some cases, logic circuit 101 may be a processor circuit, graphical processing unit (GPU), tensor processing unit (TPU), neural engine (NE), or other suitable processing circuit. Although logic circuit 101 is depicted as sending read access command 106 directly to memory circuit 102, in other embodiments, commands and data may be relayed through a memory controller circuit (not shown).

Memory circuit 102 includes control circuit 103 and memory cells 104. Although only control circuit 103 and memory cells 104 are depicted as being included in memory circuit 102, in other embodiments additional circuits, e.g., power supply circuits, reference voltage circuits, etc., may be included in memory circuit 102.

Memory cells 104 may be implemented using any suitable type of storage cell technology. In some embodiments, memory cells 104 may be implemented as dynamic memory cells that include an access transistor and a storage capacitor. Although only 12 memory cells are depicted in the embodiments of FIG. 1, in other embodiments, any suitable number of memory cells may be employed. As described below, memory cells 104 may be arranged in sub-array circuits that also include selector and amplifier circuits. Such sub-array circuits may be organized into multiple banks.

An embodiment of a given one of memory cells 104 is depicted in memory cell 115. As illustrated, memory cell 115 includes transistor 112 and capacitor 111. Transistor 112 is coupled between a first terminal of capacitor 111 and bit line 114, and is controlled by a voltage level of word line 113. A second terminal of capacitor 111 is coupled to a ground supply node (not shown).

Capacitor 111 is charged or discharged to store a bit of data. For example, if capacitor 111 is fully charged, that may correspond to storing a logical-1, while if capacitor 111 is discharged, that may correspond to storing a logical-0. As described below, to sense (or “read”) data stored in memory cell 115, the voltage level of bit line 114 is set to a pre-charge level, commonly half of the power supply voltage level, and then allowed to float while the voltage level of word line 113 is transitioned from ground potential to that of the power supply voltage level. As the voltage level of word line 113 increases, transistor 112 activates which couples capacitor 111 to bit line 114. In the case where capacitor 111 is fully charged, the voltage level of bit line 114 increases slightly from the pre-charge voltage level. Alternatively, if capacitor 111 is discharged, the voltage level of bit line 114 decreases slightly from the pre-charge voltage level. The small increase or decrease of the voltage level of bit line 114 can be sensed and the corresponding data determined.

During a pre-charge state, the voltage level of word line 113 is at or near ground potential, deactivating transistor 112. In some embodiments, a voltage level of bit line 114 may be a voltage level less than a power supply voltage level for memory circuit 102, but above ground potential. If capacitor 111 is uncharged, leakage current through transistor 112 can increase the charge in capacitor 111, potentially corrupting the data corresponding to the discharged state. If capacitor 111 is fully charged, leakage through transistor 112 onto bit line 114 can decrease the charge stored in capacitor 111, potentially corrupting the data corresponding to the charged state. To maintain the desired charge in capacitor 111, period dummy reads or “refresh operations” are performed on memory cells 104.

Control circuit 103 is configured to receive read access command 106 and check operating mode 109. In various embodiments, mode control register 105 may store information indicative of operating mode 109, and control circuit 103 may read the contents of mode control register 105 to determine operating mode 109. In some cases, logic circuit 101 may send mode command 110 to memory circuit 102, which control circuit 103 can use to modify the information stored in mode control register 105, and, therefore, modify operating mode 109. In other embodiments, memory circuit 102 may include a dedicated pin that can be used to designate a particular read command as either a destructive read operation or a non-destructive read operation. As described below, control circuit 103 may be further configured to compare address 107 to previously determined addresses or a range of addresses. Alternatively, or additionally, control circuit 103 may be configured to check a most-significant-bit of a plurality of bits included in address 107 as part of checking operating mode 109.

In response to a determination that operating mode 109 indicates a destructive read mode, control circuit 103 may be configured to sense respective bits stored in a subset of memory cells 104 that is identified by address 107. Upon completion of sensing the respective bits, control circuit 103 is further configured to abort a restore operation of the respective bits into corresponding memory cells of the subset of memory cells 104. Since the data is not restored, the data cannot be read again from the subset of memory cells 104 resulting in data that can only be “read once.” By eliminating the restore operation, the power associated with the restore operation is also eliminated thereby reducing the power consumption of memory circuit 102 and the computer system in which it resides. Moreover, eliminating the restore operation can increase the performance of the computer system since the computer system can execute a next read operation without waiting for the restore operation to complete.

As used herein, a restore operation refers to an operation in a memory circuit where data sensed from memory cells during a read operation is written back into the memory cells before the memory circuit is pre-charged prior to a subsequent operation.

In response to a determination that operating mode 109 indicates a non-destructive read mode, control circuit 103 may be configured to sense a different set of bits stored in corresponding memory cells of a different subset of the memory cells 104 identified by address 107. Upon completion of sensing respective bits, control circuit 103 may be further configured to perform a restore operation of the different set of bits into the corresponding memory cells of the different subset of memory cells 104.

In various embodiments, control circuit 103 may be configured to halt a refresh operation for one or more memory cells included in memory cells 104 in response to a determination that the one or more memory cells are designated as storing single-use data. In some embodiments, an address or range of addresses may be stored in mode control register 105. It is noted that control circuit 103 may be further configured to allow a refresh operation to be performed on the one or more memory cells in response to a determination that the one or more memory cells have not been accessed within a particular period of time.

Control circuit 103 may be implemented using any suitable combination of sequential and combinatorial logic circuits. In some cases, control circuit 103 may include one or more state machines.

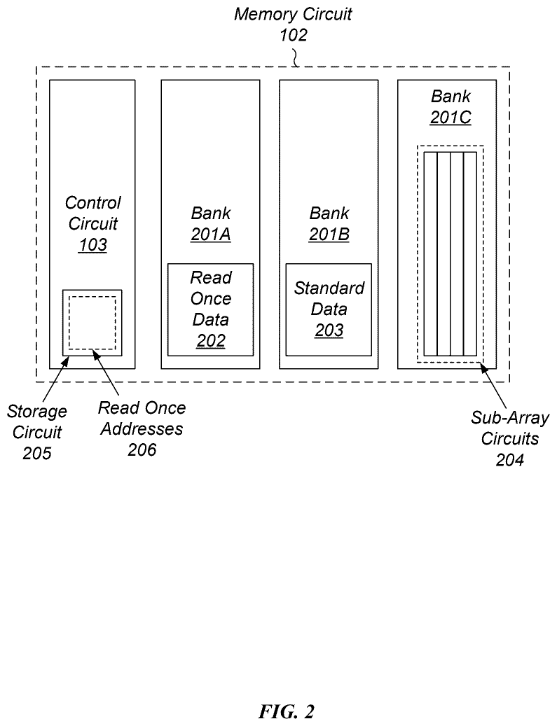

In some cases, an array of memory cells can be divided into different regions or banks. The different banks can be used to store different types of data. A block diagram of a different embodiment of memory circuit 102 that includes multiple banks is depicted in FIG. 2. As illustrated, memory circuit 102 includes control circuit 103 and banks 201A-201C. It is noted that banks 201A-201C each contain a portion of memory cells 104. Although only three banks are depicted in the embodiment of FIG. 2, in other embodiments, any suitable number of banks may be employed.

In the embodiment of FIG. 2, different banks can be used to store different types of data. For example, bank 201A may be configured to store read once data 202, while bank 201B may be configured to store standard data 203.

Upon receiving a read access command for an address associated with bank 201A, control circuit 103 may be configured to not perform a restore operation as part of the read access. The range of addresses associated with bank 201A may be stored in mode control register 105 or another suitable storage or register circuit included in control circuit 103. Such addresses may be stored in mode control register 105 during an initialization of a computer system that includes in memory circuit 102. In some cases, the size of banks 201A-201C may be dynamically adjusted during operation based on usage needs.

Since bank 201B is configured to store standard data 203, i.e., data that can be read multiple times, in response to receiving a read access command for an address associated with bank 201B, control circuit 103 may be further configured to perform a restore operation as part of the read access. Like the address range for bank 201A, the address range associated with bank 201B may also be stored in mode control register 105.

In response to a detection of a refresh condition, control circuit 103 may be configured to determine with which bank of banks 201A-201C the refresh condition is associated. Control circuit 103 may be further configured, in response to a determination that the refresh condition is associated with bank 201A, to halt a performance of a refresh operation. In various embodiments, control circuit 103 may be configured to initiate one or more refresh operations in response to a determination that the refresh condition is associated with a bank storing standard data, e.g., bank 201B.

Bank 201C includes sub-array circuits 204. It is noted that banks 201A and 201B also include respective sets of sub-array circuits that have been omitted for clarity. Although only four sub-array circuits are depicted as being included in bank 201C, in other embodiments, bank 201C may include any suitable number of sub-array circuits. As described below, sub-array circuits 204 include columns of memory cells, along with column selection circuits, pre-charge circuits, and sense amplifier circuits.

In various embodiments, control circuit 103 includes storage circuit 205 which is configured to store read once addresses 206. In different embodiments, read once addresses 206 corresponds to a range of address of read once data 202 or any other portion of any of banks 201A-201C that is used to store read once data. In other embodiments, read once addresses 206 may include a start address and a stop address that specify a range of addresses where read one data is stored.

Upon receiving read access command 106, control circuit 103 may be further configured to compare at least a portion of address 107 to read once addresses 206. In various embodiments, control circuit 103 may configured, in response to a determination that address 107 matches one of read once addresses 206, to set operation mode 109 to a destructive read mode.

In different embodiments, control circuit 103 may be further configured to update read once addresses 206 in response to receiving an update command from logic circuit 101 or any other suitable circuit. In response to an activation of a refresh operation, control circuit 103 may be further configured to halt a refresh of a row correspond to one of read once addresses 206. In some embodiments, control circuit 103 may be configured to perform a comparison of a refresh address generated by a counter circuit, or other suitable circuit, to read once addresses 206, and halt a refresh of the row using a result of the comparison.

In some embodiments, storage circuit 205 may be implemented using a register file circuit, a static random-access memory circuit, a content-addressable memory circuit, or any other suitable type of storage circuit.

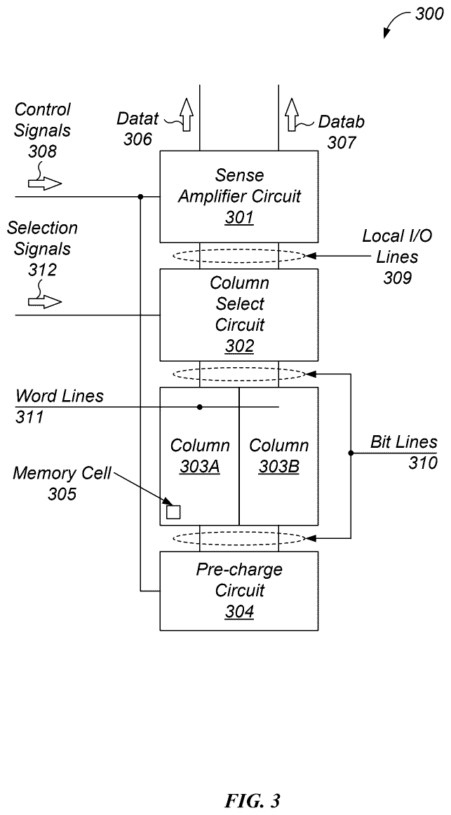

Turning to FIG. 3, a block diagram of an embodiment of a sub-array circuit is depicted. As illustrated, sub-array circuit 300 includes sense amplifier circuit 301, column select circuit 302, columns 303A and 303B, and pre-charge circuit 304. In various embodiments, sub-array circuit 300 may correspond to any of sub-array circuits 204 as depicted in FIG. 2.

Columns 303A and 303B include multiple memory cells, e.g., memory cell 305, that are coupled to corresponding ones of word lines 311. The memory cells in column 303A are coupled to a common one of bit lines 310, while the memory cells of column 303B are coupled to a different one of bit lines 310. Although bit lines 310 are depicted as signal wires, in some embodiments, bit lines 310 are grouped in pairs, with some memory cells in a column coupled to a true bit line of a pair of bit lines, and other memory cells in the column coupled to a complement bit line of the pair of bit lines. During a read access, either destructive or non-destructive, a particular one of word lines 311 will be activated based on address 107.

Column select circuit 302 is configured to couple, using selection signals 312, the bit lines from either column 303A or column 303B to local I/O lines 309. In various embodiments, column select circuit 302 may be implemented using pass gates coupled together in a wired-OR fashion onto local I/O lines 309. Different ones of the pass gates may be activated by corresponding ones of selection signals 312.

As described below, sense amplifier circuit 301 is configured, when activated by control signals 308, to generate signals Datat 306 and Datab 307 based on the respective voltage levels of local I/O lines 309. In cases where the read access is non-destructive, the respective voltage levels of Datat 306 and Datab 307 are driven back onto local I/O lines 309 and then onto the selected ones of bit lines 310 to restore the charge in the capacitor of the selected memory cell, e.g., memory cell 305. In cases where the read access is destructive, the respective voltages of Datat 306 and Datab 307 are not fed back to the selected ones of bit lines 310. Instead, the selected ones of bit lines 310 are pre-charged, storing an amount of charge in the capacitor of the selected memory cell that does not correspond to either a logical-1 or a logical-0 value.

Pre-charge circuit 304 is configured to charge bit lines 310 to a particular voltage level using control signals 308. In various embodiments, pre-charge circuit 304 may be configured to charge bit lines 310 to a voltage level substantially the same as half of the voltage level of a power supply node for memory circuit 102. In various embodiments, pre-charge circuit 304 may, during read operations without a restore operation, be activated as soon as sense amplifier circuit 301 has completed generating Datat 306 and Datab 307 using the respective voltage levels of local I/O lines 309.

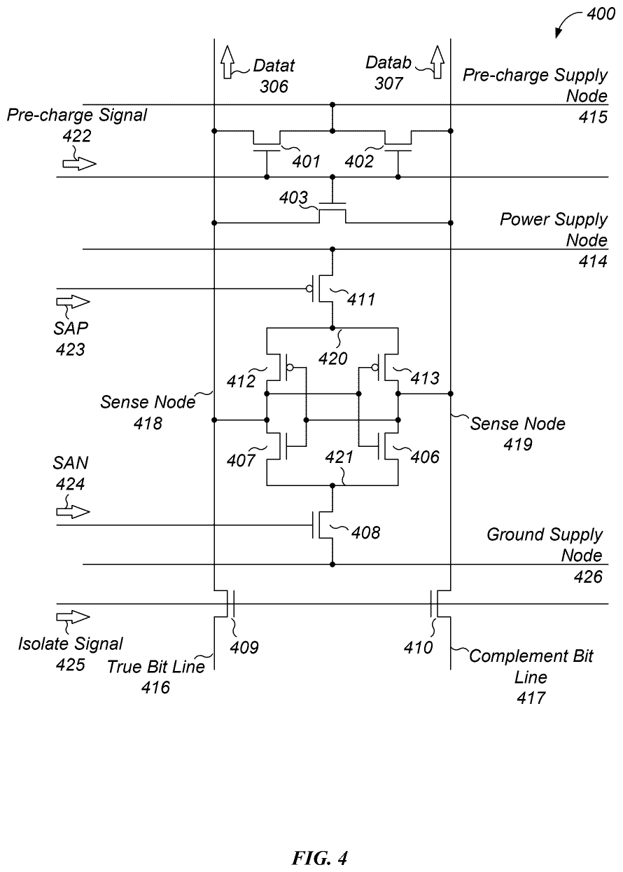

Turning to FIG. 4, a block diagram of an embodiment of a sense amplifier circuit is depicted. As illustrated, sense amplifier circuit 400 includes transistors 401-403 and 406-413. In various embodiments, sense amplifier circuit 400 may correspond to sense amplifier circuit 301 as depicted in the embodiment of FIG. 3.

Transistor 401 is coupled between sense node 418 and pre-charge supply node 415, and is controlled by pre-charge signal 422. In a similar fashion, transistor 402 is coupled between sense node 419 and pre-charge supply node 415, and is controlled by pre-charge signal 422. Transistor 403 is coupled between sense node 418 and sense node 419, and is controlled by pre-charge signal 422.

Transistor 403 is configured to couple sense node 418 to sense node 419 in response to an activation of pre-charge signal 422. Transistor 401 is configured to couple sense node 418 to pre-charge supply node 415 in response to the activation of pre-charge signal 422. In a similar fashion, transistor 402 is configured to couple sense node 419 to pre-charge supply node 415 in response to the activation of pre-charge signal 422. In various embodiments, a voltage level of pre-charge supply node 415 may correspond to half of a voltage level of power supply node 414, or any other suitable pre-charge voltage level.

Transistor 409 is coupled between sense node 418 and true bit line 416, and is controlled by isolate signal 425, while transistor 410 is coupled between sense node 419 and complement bit line 417 and is controlled by isolate signal 425. In various embodiments, true bit line 416 and complement bit line 417 may be included in bit lines 310 as depicted in the embodiment of FIG. 3.

Transistor 411 is coupled between power supply node 414 and node 420, and is controlled by an active-low sense control signal (denoted as SAP 423). Transistor 408 is coupled between node 421 and ground supply node 426, and is controlled by an active-high sense control signal (denoted as SAN 424).

Transistor 412 is coupled between node 420 and sense node 418, and is controlled by a voltage level of sense node 419, while transistor 413 is coupled between node 420 and sense node 419, and is controlled by a voltage level of sense node 418. Transistor 407 is coupled between sense node 418 and node 421, and is controlled by the voltage level of sense node 419, while transistor 406 is coupled between sense node 419 and node 421, and is controlled by the voltage level of sense node 418.

During pre-charge, a voltage level of pre-charge signal 422 is at or near the potential of power supply node 414, activating transistors 401-403, coupling sense node 418 and sense node 419 to each other and to pre-charge supply node 415. At this time, a voltage level of SAP 423 is at or near the potential of power supply node 414 deactivating transistor 411, while a voltage level of SAN 424 is at or near the potential of ground supply node 426 deactivating transistor 408. Additionally, a voltage level of isolate signal 425 is at or near the potential of ground supply node 426 deactivating transistors 409 and 410, thereby decoupling true bit line 416 from sense node 418, and decoupling complement bit line 417 from sense node 419. It is noted that respective voltage levels of true bit line 416 and complement bit line 417 may also be set to the voltage level of pre-charge supply node 415 via a bit line pre-charge circuit such as pre-charge circuit 304 as depicted in FIG. 3.

As described above, when a read access command is executed, a word line, e.g., one of word lines 311, is activated coupling the capacitor of one of memory cells 104 to a corresponding one of bit lines 310. The capacitor of the memory cell can be coupled to either of true bit line 416 or complement bit line 417. The description that follows assumes that the capacitor is coupled to true bit line 416, but the operation is similar if the capacitor is coupled to complement bit line 417.

As the word line is being activated, the voltage level of pre-charge signal 422 is set to that of ground supply node 426 deactivating transistors 401-403. Additionally, the voltage level of isolate signal 425 is set to the potential of power supply node 414, activating transistors 409 and 410 coupling true bit line 416 to sense node 418, and coupling complement bit line 417 to sense node 419. The bit line pre-charge circuit is also deactivated at this time.

As the capacitor of the selected memory is coupled to true bit line 416, a voltage level of true bit line 416 will change slightly. If the capacitor is charged, then the voltage level of true bit line 416 will increase, while if the capacitor is discharged, then the voltage level of true bit line 416 will decrease. The voltage level of complement bit line 417 will remain at the voltage level of pre-charge supply node 415 during this time.

Since true bit line 416 is coupled to sense node 418 via transistor 409, any change in the voltage level of true bit line 416 will result in a corresponding change in the voltage level of sense node 418. Once the voltage level of sense node 418 has changed, the voltage level of isolate signal 425 is set to the potential of ground supply node 426, deactivating transistors 409 and 410 and decoupling true bit line 416 from sense node 418 and decoupling complement bit line 417 from sense node 419.

Once sense nodes 418 and 419 have been isolated from true bit line 416 and complement bit line 417, respectively, the voltage level of SAP 423 is set to the potential of ground supply node 426 activating transistor 411 and coupling node 420 to power supply node 414. Additionally, the voltage level of SAN 424 is set to the potential of power supply node 414, activating transistor 408 and coupling node 421 to ground supply node 426.

With transistors 411 and 408 activated, the regenerative feedback amongst transistors 406, 407, 412, and 413 results in sense nodes 418 and 419 transitioning to the respective voltage levels of power supply node 414 or ground supply node 426 based on the voltage level of sense node 418. For example, if the voltage level of sense node 418 is slightly higher than the voltage level of pre-charge supply node 415 due to the memory cell capacitor being charged, then transistor 406 will conduct more than transistor 407, discharging sense node 419 which, in turn, results in an increase in the conduction of transistor 412. As the process continues, sense node 418 is eventually pulled to the potential of power supply node 414 resulting in a logical-1 value for Datat 306, while sense node 419 is pulled to the potential of ground supply node 426, resulting in a logical-0 value for Datab 307.

Once the respective voltage levels of sense nodes 418 and 419 have reached their final values, the operation depends on whether the read access command is destructive or non-destructive. If the read access command is destructive, the voltage level of isolate signal 425 is left at the potential of ground supply node 426 and the respective voltage levels of true bit line 416 and complement bit line 417 are set to the potential of pre-charge supply node 415 during a pre-charge operation. This results in the capacitor in the selected memory cells being charged to the potential of pre-charge supply node 415, which corresponds to neither a logical-1 or logical-0 value.

Alternatively, if the read access command is non-destructive, the voltage level of isolate signal 425 is set to the potential of power supply node 414, reactivating transistors 409 and 410. The respective voltage levels of sense nodes 418 and 419 are coupled onto true bit line 416 and complement bit line 417. In this example, the high voltage level of sense node 418 increases the voltage level of true bit line 416, eventually charging the capacitor of the selected memory cell to the potential of power supply node 414, restoring the value originally stored in the selected memory cell. Once the capacitor of the selected memory cell has been charged, the corresponding word line is deactivated, and a pre-charge operation performed.

In various embodiments, transistors 401-401 and 406-410 may be implemented as n-channel MOSFETs, FinFETs, GAAFETs, or any other suitable transconductance devices. Moreover, transistors 411-413 may be implemented as p-channel MOSFETs, FinFETs, GAAFETs, or any other suitable transconductance devices.

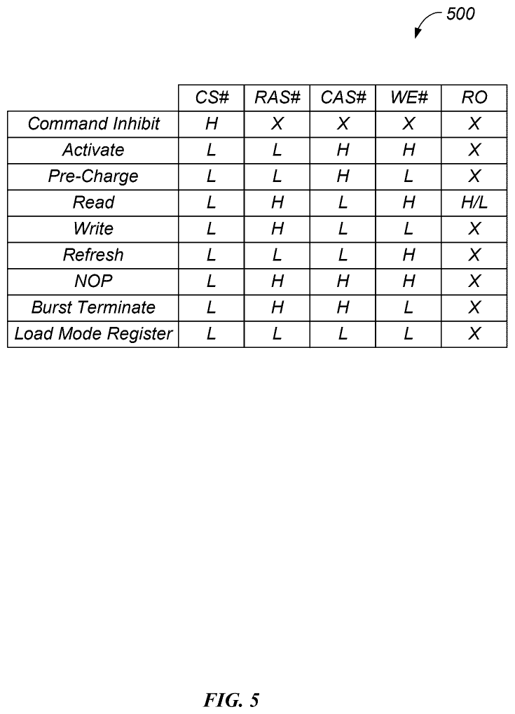

Turning to FIG. 5, a chart depicting control pin settings to implement the available commands for a memory circuit is illustrated. In some implementations of a read-once memory circuit, the available memory commands in memory command chart 500 may be used to implement read-once operations, thereby reducing an amount of modifications to the memory circuit that would have to be made to support read-once operations.

As described above, the load mode register command may be used to set a particular value in mode control register 105. The particular value can be indicative of a read-once mode of operation where all read commands are performed without accompanying restore operations.

Alternatively, another technique for implementing read-once operations would be to make all read accesses read-once accesses and then having a circuit, e.g., logic circuit 101, force a pre-charge command after a particular read access if that read access is to be a non-destructive read.

A different technique to differentiate between standard read operations and read-once operations would be the use of an additional input pin, i.e., an RO pin, on memory circuit 102. When a read access command is received by memory circuit 102, whether the read access is treated as a destructive or non-destructive read operation would be determined by the state of the RO pin at the time the read access command is received.

In some embodiments, changes may be made to a programming language to introduce a new variable type that can be used to differentiate between destructive and non-destructive read operations. A compiler could, in various embodiments, use the new variable type to generate appropriate flags used by a runtime system using read-once memory to store variables of the new type.

To summarize, various embodiments of a read-once memory circuit are disclosed. Broadly speaking, the read-once memory circuit can include a control circuit and a plurality of memory cells configured to store respective bits of data. The control circuit can be configured to receive a particular read access command that includes a particular address, and check an operating mode. In response to a determination that the operating mode is a destructive read mode, the control circuit can be further configured to sense a particular set of bits stored in corresponding memory cells of a particular subset of the plurality of memory cells identified by the particular address, and abort, upon a completion of sensing the particular set of bits, a particular restore operation of the particular set of bits into the corresponding memory cells of the particular subset of the plurality of memory cells.

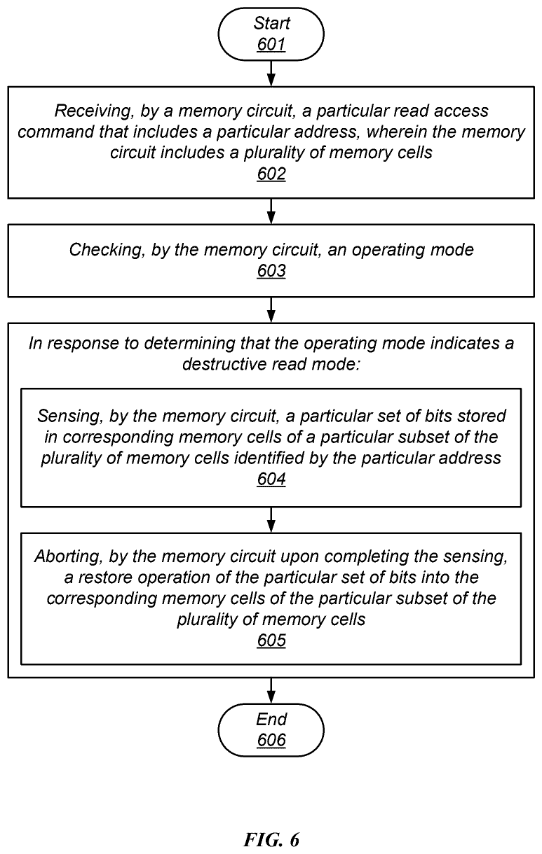

Turning to FIG. 6, a flow diagram depicting an embodiment of a method for operating a read-once memory is depicted. The method, which may be applied to various memory circuits, e.g., memory circuit 102 as depicted in FIG. 1, begins in block 601.

The method includes receiving, by a memory circuit, a particular read access command that includes a particular address (block 602). In various embodiments, the memory circuit includes a plurality of memory cells.

The method also includes checking, by the memory circuit, an operating mode (block 603). In some embodiments, the memory circuit includes a mode control register circuit. In such cases, checking the operating mode may include retrieving mode information stored in the mode control register circuit. In various embodiments, the method may also include receiving, by the memory circuit, an update read-mode signal, and storing, using the update read-mode signal, a modified version of the mode information into the mode control register. In other embodiments, the method may additionally include, in response to initializing a computer system that includes the memory circuit, storing initial mode information in the mode control register circuit.

In some embodiments, checking the operation mode may further include checking, by the memory circuit, a most-significant-bit of a plurality of bits included in the particular address, and determining the operating mode based on a value of the most-significant-bit. In other embodiments, checking the operation mode additionally include performing a comparison of at least a portion of the particular address to a list or range of previously determined read once addresses, and determining the operating mode using a result of the comparison.

The method further includes, in response to determining that the operating mode indicates a destructive read mode, sensing, by the memory circuit, a particular set of bits stored in corresponding memory cells of a particular subset of the plurality of memory cells identified by the particular address (block 604).

The method also includes, in response to determining that the operating mode indicates the destructive read mode, aborting, by the memory circuit upon completing the sensing, a restore operation of the particular set of bits into the corresponding memory cells of the particular subset of the plurality of memory cells.

The method may further include receiving, by the memory circuit, a different read access command that includes a different address. In such cases, the method includes, in response to determining that the operating mode indicates a non-destructive read mode, sensing, by the memory circuit, a different set of bits stored in corresponding memory cells of a different subset of memory cells identified by the different address, and performing, by the memory circuit upon completing the sensing, a restore operation of a different set of bits into the corresponding memory cells of the different subset of the plurality of memory cells.

In other embodiments, the method may also include receiving, by the memory circuit, a different read access command that includes a different address, and receiving a read-mode signal. In such cases, the method includes, in response to determining that the read-mode signal indicates the destructive read mode, sensing a different set of bits stored in corresponding memory cells of a different subset of the plurality of memory cells identified by the different address, and aborting, upon completing the sensing, a different restore operation of the different set of bits into the corresponding memory cells of the different subset of the plurality of memory cells.

In various embodiments, the method may also include halting, by the memory circuit, at least one refresh operation in response to determining that the operating mode indicates the destructive read mode. The method concludes in block 606.

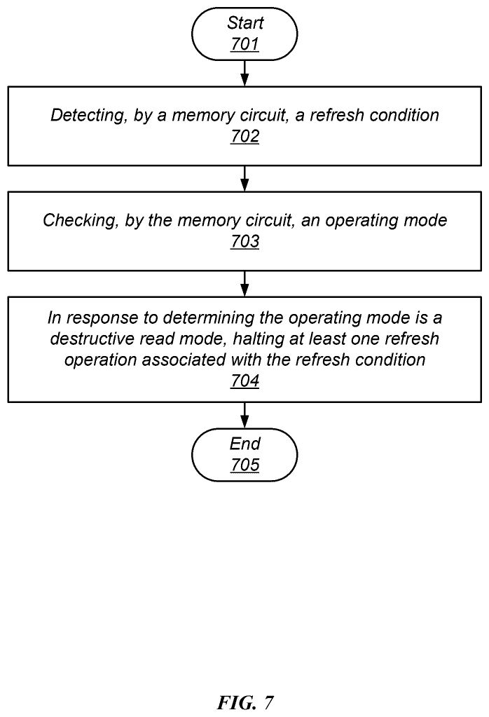

Turning to FIG. 7, a flow diagram depicting an embodiment of a method for refreshing a read-once memory circuit is illustrated. The method which may be applied to various memory circuits, e.g., memory circuit 102 as depicted in FIG. 1, begins in block 701.

The method includes detecting, by a memory circuit, a refresh condition (block 702). In some cases, the refresh condition may include receiving a refresh command. In various embodiments, the refresh command may include an address or range of addresses to refresh. In other embodiments, the refresh condition may include a timer circuit reaching a particular value indicating a refresh of one or more addresses is to be performed.

The method also includes checking, by the memory circuit, an operating mode (block 703). In some embodiments, the memory circuit includes a mode control register circuit. In such cases, checking the operating mode may include retrieving mode information stored in the mode control register circuit. In some embodiments, checking the operation mode may further include checking, by the memory circuit, a most-significant-bit of a plurality of bits included in the particular address, and determining the operating mode based on a value of the most-significant-bit. In other embodiments, checking the operation mode additionally include performing a comparison of at least a portion of the particular address to a list or range of previously determined read once addresses, and determining the operating mode using a result of the comparison.

The method further includes, in response to determining the operating mode is a destructive read mode, halting at least one refresh operation associated with the refresh condition (block 704). In some embodiments, the method may additionally include generating, by the memory circuit, a ready signal indicating that a refresh operation has not been performed and that the memory circuit is ready for further commands. The method ends in block 705.

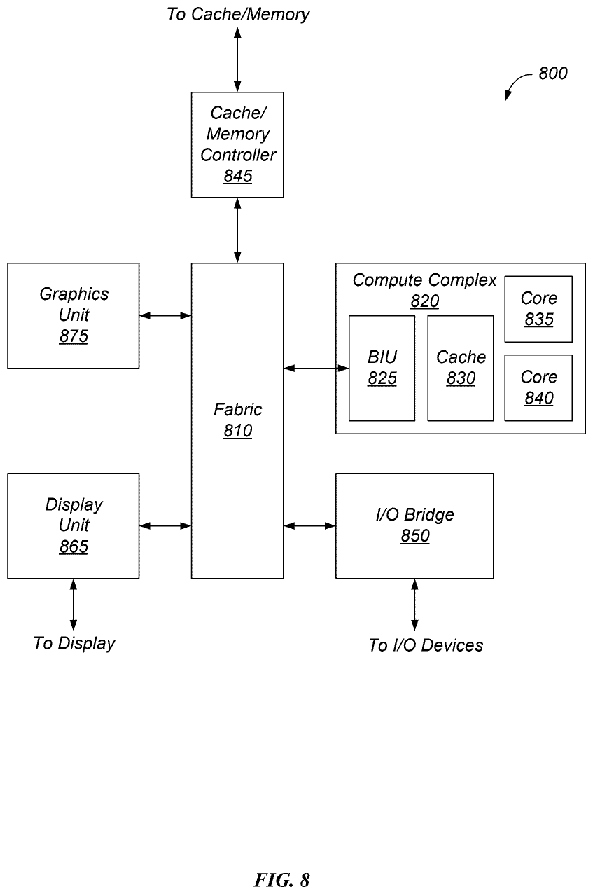

Referring now to FIG. 8, a block diagram illustrating an example embodiment of a device is shown. In some embodiments, elements of device 800 may be included within a system-on-a-chip. In some embodiments, device 800 may be included in a mobile device, which may be battery-powered. Therefore, power consumption by device 800 may be an important design consideration. In the illustrated embodiment, device 800 includes fabric 810, compute complex 820, input/output (I/O) bridge 850, cache/memory controller 845, graphics unit 875, and display unit 865. In some embodiments, device 800 may include other components (not shown) in addition to, or in place of, the illustrated components, such as video processor encoders and decoders, image processing or recognition elements, computer vision elements, etc.

Fabric 810 may include various interconnects, buses, MUX's, controllers, etc., and may be configured to facilitate communication between various elements of device 800. In some embodiments, portions of fabric 810 may be configured to implement various different communication protocols. In other embodiments, fabric 810 may implement a single communication protocol, and elements coupled to fabric 810 may convert from the single communication protocol to other communication protocols internally.

In the illustrated embodiment, compute complex 820 includes bus interface unit (BIU) 825, cache 830, and cores 835 and 840. In various embodiments, compute complex 820 may include various numbers of processors, processor cores, and caches. For example, compute complex 820 may include 1, 2, or 4 processor cores, or any other suitable number. In one embodiment, cache 830 is a set associative L2 cache. In some embodiments, cores 835 and 840 may include internal instruction and data caches. In some embodiments, a coherency unit (not shown) in fabric 810, cache 830, or elsewhere in device 800, may be configured to maintain coherency between various caches of device 900. BIU 825 may be configured to manage communication between compute complex 820 and other elements of device 800. Processor cores, such as cores 835 and 840, may be configured to execute instructions of a particular instruction set architecture (ISA) which may include operating system instructions and user application instructions. These instructions may be stored in a computer readable medium such as a memory coupled to cache/memory controller 845 as discussed below.

As used herein, the term “coupled to” may indicate one or more connections between elements, and a coupling may include intervening elements. For example, in FIG. 8, graphics unit 875 may be described as “coupled to” a memory through fabric 810 and cache/memory controller 845. In contrast, in the illustrated embodiment of FIG. 8, graphics unit 875 is “directly coupled” to fabric 810 because there are no intervening elements.

Cache/memory controller 845 may be configured to manage transfer of data between fabric 810 and one or more caches and memories. For example, cache/memory controller 845 may be coupled to an L3 cache, which may, in turn, be coupled to a system memory. In other embodiments, cache/memory controller 845 may be directly coupled to a memory. In some embodiments, cache/memory controller 845 may include one or more internal caches. Memory coupled to cache/memory controller 845 may be any type of volatile memory, such as dynamic random access memory (DRAM), synchronous DRAM (SDRAM), double data rate (DDR, DDR2, DDR3, etc.) SDRAM (including mobile versions of SDRAMs such as mDDR3, etc., and/or low power versions of SDRAMs such as LPDDR4, etc.), RAMBUS DRAM (RDRAM), static RAM (SRAM), etc. One or more memory devices may be coupled onto a circuit board to form memory modules such as single inline memory modules (SIMMs), dual inline memory modules (DIMMs), etc. Alternatively, the devices may be mounted with an integrated circuit in a chip-on-chip configuration, a package-on-package configuration, or a multi-chip module configuration. Memory coupled to cache/memory controller 845 may be any type of non-volatile memory such as NAND flash memory, NOR flash memory, nano RAM (NRAM), magneto-resistive RAM (MRAM), phase change RAM (PRAM), Racetrack memory, Memristor memory, etc. As noted above, this memory may store program instructions executable by compute complex 820 to cause the computing device to perform functionality described herein.

Graphics unit 875 may include one or more processors, e.g., one or more graphics processing units (GPUs). Graphics unit 875 may receive graphics-oriented instructions, such as OPENGL®, Metal®, or DIRECT3D® instructions, for example. Graphics unit 875 may execute specialized GPU instructions or perform other operations based on the received graphics-oriented instructions. Graphics unit 875 may generally be configured to process large blocks of data in parallel, and may build images in a frame buffer for output to a display, which may be included in the device or may be a separate device. Graphics unit 875 may include transform, lighting, triangle, and rendering engines in one or more graphics processing pipelines. Graphics unit 875 may output pixel information for display images. Graphics unit 875, in various embodiments, may include programmable shader circuitry which may include highly parallel execution cores configured to execute graphics programs, which may include pixel tasks, vertex tasks, and compute tasks (which may or may not be graphics-related).

Display unit 865 may be configured to read data from a frame buffer and provide a stream of pixel values for display. Display unit 865 may be configured as a display pipeline in some embodiments. Additionally, display unit 865 may be configured to blend multiple frames to produce an output frame. Further, display unit 865 may include one or more interfaces (e.g., MIPI® or embedded display port (eDP)) for coupling to a user display (e.g., a touchscreen or an external display).

I/O bridge 850 may include various elements configured to implement universal serial bus (USB) communications, security, audio, and low-power always-on functionality, for example. I/O bridge 850 may also include interfaces such as pulse-width modulation (PWM), general-purpose input/output (GPIO), serial peripheral interface (SPI), and inter-integrated circuit (I2C), for example. Various types of peripherals and devices may be coupled to device 800 via I/O bridge 850.

In some embodiments, device 800 includes network interface circuitry (not explicitly shown), which may be connected to fabric 810 or I/O bridge 850. The network interface circuitry may be configured to communicate via various networks, which may be wired, wireless, or both. For example, the network interface circuitry may be configured to communicate via a wired local area network, a wireless local area network (e.g., via Wi-Fi™), or a wide area network (e.g., the Internet or a virtual private network). In some embodiments, the network interface circuitry is configured to communicate via one or more cellular networks that use one or more radio access technologies. In some embodiments, the network interface circuitry is configured to communicate using device-to-device communications (e.g., Bluetooth® or Wi-Fi™ Direct), etc. In various embodiments, the network interface circuitry may provide device 800 with connectivity to various types of other devices and networks.

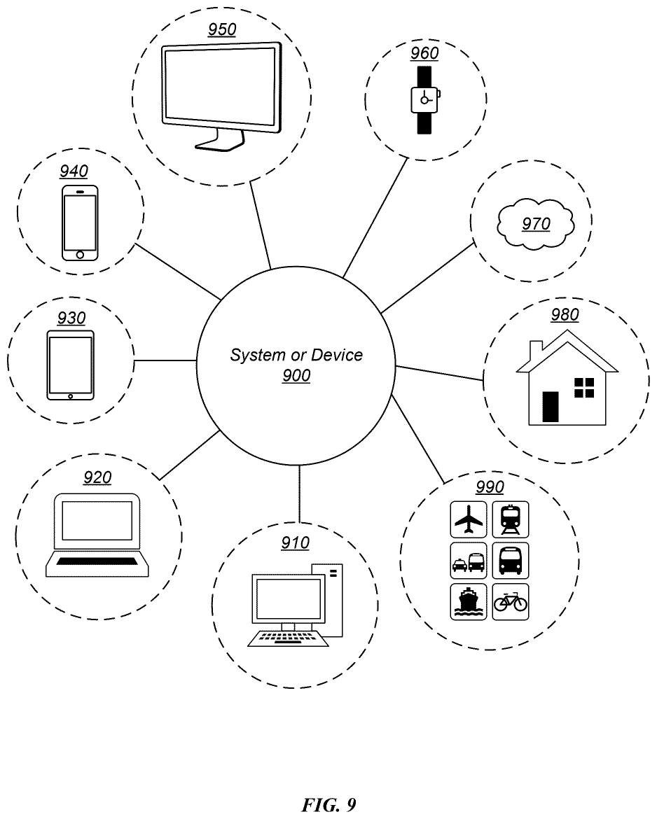

Turning now to FIG. 9, various types of systems that may include any of the circuits, devices, or systems discussed above are illustrated. System or device 900, which may incorporate or otherwise utilize one or more of the techniques described herein, may be utilized in a wide range of areas. For example, system or device 900 may be utilized as part of the hardware of systems such as a desktop computer 910, laptop computer 920, tablet computer 930, cellular or mobile phone 940, or television 950 (or set-top box coupled to a television).

Similarly, disclosed elements may be utilized in a wearable device 960, such as a smartwatch or a health-monitoring device. Smartwatches, in many embodiments, may implement a variety of different functions—for example, access to email, cellular service, calendar, health monitoring, etc. A wearable device may also be designed solely to perform health-monitoring functions, such as monitoring a user's vital signs, performing epidemiological functions such as contact tracing, providing communication to an emergency medical service, etc. Other types of devices are also contemplated, including devices worn on the neck, devices implantable in the human body, glasses or a helmet designed to provide computer-generated reality experiences such as those based on augmented and/or virtual reality, etc.

System or device 900 may also be used in various other contexts. For example, system or device 900 may be utilized in the context of a network switch that routes data packets from one device to another. Alternatively or additionally, system or device 900 may be included in a server computer system, such as a dedicated server or on shared hardware that implements a cloud-based service 970. Still further, system or device 900 may be implemented in a wide range of specialized everyday devices, including devices 980 commonly found in the home such as refrigerators, thermostats, security cameras, etc. The interconnection of such devices is often referred to as the “Internet of Things” (IoT). Elements may also be implemented in various modes of transportation. For example, system or device 900 could be employed in the control systems, guidance systems, entertainment systems, etc. of various types of vehicles 990.

The applications illustrated in FIG. 9 are merely exemplary and are not intended to limit the potential future applications of disclosed systems or devices. Other example applications include, without limitation: portable gaming devices, music players, data storage devices, unmanned aerial vehicles, etc.

The present disclosure has described various example circuits in detail above. It is intended that the present disclosure cover not only embodiments that include such circuitry, but also a computer-readable storage medium that includes design information that specifies such circuitry. Accordingly, the present disclosure is intended to support claims that cover not only an apparatus that includes the disclosed circuitry, but also a storage medium that specifies the circuitry in a format that programs a computing system to generate a simulation model of the hardware circuit, programs a fabrication system configured to produce hardware (e.g., an integrated circuit) that includes the disclosed circuitry, etc. Claims to such a storage medium are intended to cover, for example, an entity that produces a circuit design, but does not itself perform complete operations such as design simulation, design synthesis, circuit fabrication, etc.

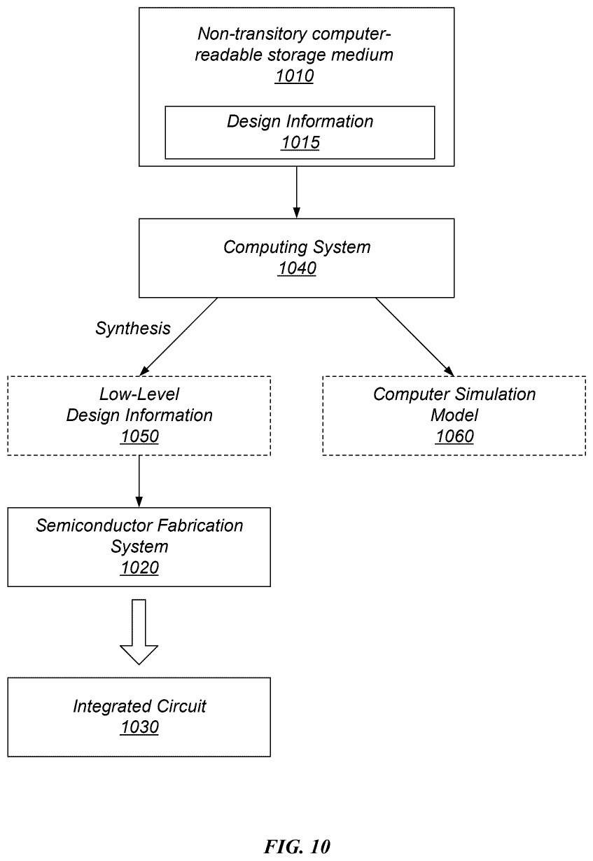

FIG. 10 is a block diagram illustrating an example of a non-transitory computer-readable storage medium that stores design information 1015, according to some embodiments. In the illustrated embodiment, computing system 1040 is configured to process design information 1015. This may include executing instructions included in design information 1015, interpreting instructions included in design information 1015, compiling, transforming, or otherwise updating design information 1015, etc. Therefore, design information 1015 controls computing system 1040 (e.g., by programming computing system 1040) to perform various operations discussed below, in some embodiments.

In the illustrated example, computing system 1040 processes design information 1015 to generate both computer simulation model of hardware circuit 1060 and low-level design information 1050. In other embodiments, computing system 1040 may generate only one of these outputs, may generate other outputs based on design information 1015, or both. Regarding computer simulation model of hardware circuit 1060, computing system 1040 may execute instructions of a hardware description language that includes register transfer level (RTL) code, behavioral code, structural code, or some combination thereof. The simulation model may perform the functionality specified by design information 1015, facilitate verification of the functional correctness of the hardware design, generate power consumption estimates, generate timing estimates, etc.

In the illustrated example, computing system 1040 also processes design information 1015 to generate low-level design information 1050 (e.g., gate-level design information, a netlist, etc.). This may include synthesis operations, as shown, such as constructing a multi-level network, optimizing the network using technology-independent techniques, technology dependent techniques, or both, and outputting a network of gates (with potential constraints based on available gates in a technology library, sizing, delay, power, etc.). Based on low-level design information 1050 (potentially among other inputs), semiconductor fabrication system 1020 is configured to fabricate integrated circuit 1030 (which may correspond to functionality of the computer simulation model of hardware circuit 1060). Note that computing system 1040 may generate different simulation models based on design information at various levels of description, including low-level design information 1050, design information 1015, and so on. The data representing low-level design information 1050 and computer simulation model of hardware circuit 1060 may be stored on non-transitory computer-readable storage medium 1010, or on one or more other media.

In some embodiments, low-level design information 1050 controls (e.g., programs) semiconductor fabrication system 1020 to fabricate integrated circuit 1030. Thus, when processed by the fabrication system, the design information may program the fabrication system to fabricate a circuit that includes various circuitry disclosed herein.

Non-transitory computer-readable storage medium 1010 may comprise any of various appropriate types of memory devices or storage devices. Non-transitory computer-readable storage medium 1010 may be an installation medium, e.g., a CD-ROM, floppy disks, or tape device; a computer system memory or random access memory such as DRAM, DDR RAM, SRAM, EDO RAM, Rambus RAM, etc. ; a non-volatile memory such as a Flash memory, magnetic media, e.g., a hard drive, or optical storage; registers, or other similar types of memory elements, etc. Non-transitory computer-readable storage medium 1010 may include other types of non-transitory memory as well, or combinations thereof. Accordingly, non-transitory computer-readable storage medium 1010 may include two or more memory media, which may reside in different locations—for example, in different computer systems that are connected over a network.

Design information 1015 may be specified using any of various appropriate computer languages, including hardware description languages such as, without limitation: VHDL, Verilog, SystemC, SystemVerilog, RHDL, M, MyHDL, etc. The format of various design information may be recognized by one or more applications executed by computing system 1040, semiconductor fabrication system 1020, or both. In some embodiments, design information 1015 may also include one or more cell libraries that specify the synthesis, layout, or both of integrated circuit 1030. In some embodiments, design information 1015 is specified in whole, or in part, in the form of a netlist that specifies cell library elements and their connectivity. Design information discussed herein, taken alone, may or may not include sufficient information for fabrication of a corresponding integrated circuit. For example, design information may specify the circuit elements to be fabricated but not their physical layout. In this case, design information may be combined with layout information to actually fabricate the specified circuitry.

Integrated circuit 1030 may, in various embodiments, include one or more custom macrocells, such as memories, analog or mixed-signal circuits, and the like. In such cases, design information 1015 may include information related to included macrocells. Such information may include, without limitation, schematics capture database, mask design data, behavioral models, and device or transistor level netlists. Mask design data may be formatted according to graphic data system (GDSII), or any other suitable format.

Semiconductor fabrication system 1020 may include any of various appropriate elements configured to fabricate integrated circuits. This may include, for example, elements for depositing semiconductor materials (e.g., on a wafer, which may include masking), removing materials, altering the shape of deposited materials, modifying materials (e.g., by doping materials or modifying dielectric constants using ultraviolet processing), etc. Semiconductor fabrication system 1020 may also be configured to perform various testing of fabricated circuits for correct operation.

In various embodiments, integrated circuit 1030 and computer simulation model of hardware circuit 1060 are configured to operate according to a circuit design specified by design information 1015, which may include performing any of the functionality described herein. For example, integrated circuit 1030 may include any of various elements shown in FIGS. 1-4. Further, integrated circuit 1030 may be configured to perform various functions described herein in conjunction with other components. Further, the functionality described herein may be performed by multiple connected integrated circuits.

As used herein, a phrase of the form “design information that specifies a design of a circuit configured to . . . ” does not imply that the circuit in question must be fabricated in order for the element to be met. Rather, this phrase indicates that the design information describes a circuit that, upon being fabricated, will be configured to perform the indicated actions or will include the specified components. Similarly, stating “instructions of a hardware description programming language” that are “executable” to program a computing system to generate a computer simulation model does not imply that the instructions must be executed in order for the element to be met, but rather, specifies characteristics of the instructions. Additional features relating to the model (or the circuit represented by the model) may similarly relate to characteristics of the instructions, in this context. Therefore, an entity that sells a computer-readable medium with instructions that satisfy recited characteristics may provide an infringing product, even if another entity actually executes the instructions on the medium.

Note that a given design, at least in the digital logic context, may be implemented using a multitude of different gate arrangements, circuit technologies, etc. As one example, different designs may select or connect gates based on design tradeoffs (e.g., to focus on power consumption, performance, circuit area, etc.). Further, different manufacturers may have proprietary libraries, gate designs, physical gate implementations, etc. Different entities may also use different tools to process design information at various layers (e.g., from behavioral specifications to physical layout of gates).

Once a digital logic design is specified, however, those skilled in the art need not perform substantial experimentation or research to determine those implementations. Rather, those of skill in the art understand procedures to reliably and predictably produce one or more circuit implementations that provide the function described by design information 1015. The different circuit implementations may affect the performance, area, power consumption, etc. of a given design (potentially with tradeoffs between different design goals), but the logical function does not vary among the different circuit implementations of the same circuit design.

In some embodiments, the instructions included in design information 1015 provide RTL information (or other higher-level design information) and are executable by the computing system to synthesize a gate-level netlist that represents the hardware circuit based on the RTL information as an input. Similarly, the instructions may provide behavioral information and be executable by the computing system to synthesize a netlist or other lower-level design information included in low-level design information 1050. Low-level design information 1050 may program semiconductor fabrication system 1020 to fabricate integrated circuit 1030.

The present disclosure includes references to an “embodiment” or groups of “embodiments” (e.g., “some embodiments” or “various embodiments”). Embodiments are different implementations or instances of the disclosed concepts. References to “an embodiment,” “one embodiment,” “a particular embodiment,” and the like do not necessarily refer to the same embodiment. A large number of possible embodiments are contemplated, including those specifically disclosed, as well as modifications or alternatives that fall within the spirit or scope of the disclosure.

This disclosure may discuss potential advantages that may arise from the disclosed embodiments. Not all implementations of these embodiments will necessarily manifest any or all of the potential advantages. Whether an advantage is realized for a particular implementation depends on many factors, some of which are outside the scope of this disclosure. In fact, there are a number of reasons why an implementation that falls within the scope of the claims might not exhibit some or all of any disclosed advantages. For example, a particular implementation might include other circuitry outside the scope of the disclosure that, in conjunction with one of the disclosed embodiments, negates or diminishes one or more of the disclosed advantages. Furthermore, suboptimal design execution of a particular implementation (e.g., implementation techniques or tools) could also negate or diminish disclosed advantages. Even assuming a skilled implementation, realization of advantages may still depend upon other factors such as the environmental circumstances in which the implementation is deployed. For example, inputs supplied to a particular implementation may prevent one or more problems addressed in this disclosure from arising on a particular occasion, with the result that the benefit of its solution may not be realized. Given the existence of possible factors external to this disclosure, it is expressly intended that any potential advantages described herein are not to be construed as claim limitations that must be met to demonstrate infringement. Rather, identification of such potential advantages is intended to illustrate the type(s) of improvement available to designers having the benefit of this disclosure. That such advantages are described permissively (e.g., stating that a particular advantage “may arise”) is not intended to convey doubt about whether such advantages can in fact be realized, but rather to recognize the technical reality that realization of such advantages often depends on additional factors.

Unless stated otherwise, embodiments are non-limiting. That is, the disclosed embodiments are not intended to limit the scope of claims that are drafted based on this disclosure, even where only a single example is described with respect to a particular feature. The disclosed embodiments are intended to be illustrative rather than restrictive, absent any statements in the disclosure to the contrary. The application is thus intended to permit claims covering disclosed embodiments, as well as such alternatives, modifications, and equivalents that would be apparent to a person skilled in the art having the benefit of this disclosure.

For example, features in this application may be combined in any suitable manner. Accordingly, new claims may be formulated during prosecution of this application (or an application claiming priority thereto) to any such combination of features. In particular, with reference to the appended claims, features from dependent claims may be combined with those of other dependent claims where appropriate, including claims that depend from other independent claims. Similarly, features from respective independent claims may be combined where appropriate.

Accordingly, while the appended dependent claims may be drafted such that each depends on a single other claim, additional dependencies are also contemplated. Any combinations of features in the dependent claims that are consistent with this disclosure are contemplated and may be claimed in this or another application. In short, combinations are not limited to those specifically enumerated in the appended claims.

Where appropriate, it is also contemplated that claims drafted in one format or statutory type (e.g., apparatus) are intended to support corresponding claims of another format or statutory type (e.g., method).

Because this disclosure is a legal document, various terms and phrases may be subject to administrative and judicial interpretation. Public notice is hereby given that the following paragraphs, as well as definitions provided throughout the disclosure, are to be used in determining how to interpret claims that are drafted based on this disclosure.

References to a singular form of an item (i.e., a noun or noun phrase preceded by “a,” “an,” or “the”) are, unless context clearly dictates otherwise, intended to mean “one or more.” Reference to “an item” in a claim thus does not, without accompanying context, preclude additional instances of the item. A “plurality” of items refers to a set of two or more of the items.

The word “may” is used herein in a permissive sense (i.e., having the potential to, being able to) and not in a mandatory sense (i.e., must).

The terms “comprising” and “including,” and forms thereof, are open-ended and mean “including, but not limited to.”

When the term “or” is used in this disclosure with respect to a list of options, it will generally be understood to be used in the inclusive sense unless the context provides otherwise. Thus, a recitation of “x or y” is equivalent to “x or y, or both,” and thus covers 1) x but not y, 2) y but not x, and 3) both x and y. On the other hand, a phrase such as “either x or y, but not both” makes clear that “or” is being used in the exclusive sense.

A recitation of “w, x, y, or z, or any combination thereof” or “at least one of . . . w, x, y, and z” is intended to cover all possibilities involving a single element up to the total number of elements in the set. For example, given the set [w, x, y, z], these phrasings cover any single element of the set (e.g., w but not x, y, or z), any two elements (e.g., w and x, but not y or z), any three elements (e.g., w, x, and y, but not z), and all four elements. The phrase “at least one of . . . w, x, y, and z” thus refers to at least one element of the set [w, x, y, z], thereby covering all possible combinations in this list of elements. This phrase is not to be interpreted to require that there is at least one instance of w, at least one instance of x, at least one instance of y, and at least one instance of z.

Various “labels” may precede nouns or noun phrases in this disclosure. Unless context provides otherwise, different labels used for a feature (e.g., “first circuit,” “second circuit,” “particular circuit,” “given circuit,” etc.) refer to different instances of the feature. Additionally, the labels “first,” “second,” and “third,” when applied to a feature, do not imply any type of ordering (e.g., spatial, temporal, logical, etc.), unless stated otherwise.

The phrase “based on” is used to describe one or more factors that affect a determination. This term does not foreclose the possibility that additional factors may affect the determination. That is, a determination may be solely based on specified factors, or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

The phrases “in response to” and “responsive to” describe one or more factors that trigger an effect. This phrase does not foreclose the possibility that additional factors may affect or otherwise trigger the effect, either jointly with the specified factors or independent from the specified factors. That is, an effect may be solely in response to those factors, or may be in response to the specified factors as well as other, unspecified factors. Consider the phrase “perform A in response to B.” This phrase specifies that B is a factor that triggers the performance of A, or that triggers a particular result for A. This phrase does not foreclose that performing A may also be in response to some other factor, such as C. This phrase also does not foreclose that performing A may be jointly in response to B and C. This phrase is also intended to cover an embodiment in which A is performed solely in response to B. As used herein, the phrase “responsive to” is synonymous with the phrase “responsive at least in part to.” Similarly, the phrase “in response to” is synonymous with the phrase “at least in part in response to.”

Within this disclosure, different entities (which may variously be referred to as “units,” “circuits,” other components, etc.) may be described or claimed as “configured” to perform one or more tasks or operations. This formulation—[entity] configured to [perform one or more tasks]—is used herein to refer to structure (i.e., something physical). More specifically, this formulation is used to indicate that this structure is arranged to perform the one or more tasks during operation. A structure can be said to be “configured to” perform some task even if the structure is not currently being operated. Thus, an entity described or recited as being “configured to” perform some task refers to something physical, such as a device, a circuit, or a system having a processor unit and a memory storing program instructions executable to implement the task, etc. This phrase is not used herein to refer to something intangible.

In some cases, various units/circuits/components may be described herein as performing a set of tasks or operations. It is understood that those entities are “configured to” perform those tasks/operations, even if not specifically noted.

The term “configured to” is not intended to mean “configurable to.” An unprogrammed FPGA, for example, would not be considered to be “configured to” perform a particular function. This unprogrammed FPGA may be “configurable to” perform that function, however. After appropriate programming, the FPGA may then be said to be “configured to” perform the particular function.

For purposes of United States patent applications based on this disclosure, reciting in a claim that a structure is “configured to” perform one or more tasks is expressly intended not to invoke 35 U.S.C. § 112(f) for that claim element. Should Applicant wish to invoke Section 112(f) during prosecution of a United States patent application based on this disclosure, it will recite claim elements using the “means for” [performing a function] construct.

Different “circuits” may be described in this disclosure. These circuits or “circuitry” constitute hardware that includes various types of circuit elements, such as combinatorial logic, clocked storage devices (e.g., flip-flops, registers, latches, etc.), finite state machines, memory (e.g., random-access memory, embedded dynamic random-access memory), programmable logic arrays, and so on. Circuitry may be custom designed, or taken from standard libraries. In various implementations, circuitry can, as appropriate, include digital components, analog components, or a combination of both. Certain types of circuits may be commonly referred to as “units” (e.g., a decode unit, an arithmetic logic unit (ALU), a functional unit, a memory management unit (MMU), etc.). Such units also refer to circuits or circuitry.

The disclosed circuits/units/components and other elements illustrated in the drawings and described herein thus include hardware elements such as those described in the preceding paragraph. In many instances, the internal arrangement of hardware elements within a particular circuit may be specified by describing the function of that circuit. For example, a particular “decode unit” may be described as performing the function of “processing an opcode of an instruction and routing that instruction to one or more of a plurality of functional units,” which means that the decode unit is “configured to” perform this function. This specification of function is sufficient, to those skilled in the computer arts, to connote a set of possible structures for the circuit.

In various embodiments, as discussed in the preceding paragraph, circuits, units, and other elements may be defined by the functions or operations that they are configured to implement. The arrangement of such circuits/units/components with respect to each other and the manner in which they interact form a microarchitectural definition of the hardware that is ultimately manufactured in an integrated circuit or programmed into an FPGA to form a physical implementation of the microarchitectural definition. Thus, the microarchitectural definition is recognized by those of skill in the art as a structure from which many physical implementations may be derived, all of which fall into the broader structure described by the microarchitectural definition. That is, a skilled artisan presented with the microarchitectural definition supplied in accordance with this disclosure may, without undue experimentation and with the application of ordinary skill, implement the structure by coding the description of the circuits/units/components in a hardware description language (HDL) such as Verilog or VHDL. The HDL description is often expressed in a fashion that may appear to be functional. But to those of skill in the art in this field, this HDL description is the manner that is used to transform the structure of a circuit, unit, or component to the next level of implementational detail. Such an HDL description may take the form of behavioral code (which is typically not synthesizable), register transfer language (RTL) code (which, in contrast to behavioral code, is typically synthesizable), or structural code (e.g., a netlist specifying logic gates and their connectivity). The HDL description may subsequently be synthesized against a library of cells designed for a given integrated circuit fabrication technology, and may be modified for timing, power, and other reasons to result in a final design database that is transmitted to a foundry to generate masks and ultimately produce the integrated circuit. Some hardware circuits, or portions thereof, may also be custom-designed in a schematic editor and captured into the integrated circuit design along with synthesized circuitry. The integrated circuits may include transistors and other circuit elements (e.g., passive elements such as capacitors, resistors, inductors, etc.) and interconnect between the transistors and circuit elements. Some embodiments may implement multiple integrated circuits coupled together to implement the hardware circuits, and/or discrete elements may be used in some embodiments. Alternatively, the HDL design may be synthesized to a programmable logic array such as a field programmable gate array (FPGA) and may be implemented in the FPGA. This decoupling between the design of a group of circuits and the subsequent low-level implementation of these circuits commonly results in the scenario in which the circuit or logic designer never specifies a particular set of structures for the low-level implementation beyond a description of what the circuit is configured to do, as this process is performed at a different stage of the circuit implementation process.

The fact that many different low-level combinations of circuit elements may be used to implement the same specification of a circuit results in a large number of equivalent structures for that circuit. As noted, these low-level circuit implementations may vary according to changes in the fabrication technology, the foundry selected to manufacture the integrated circuit, the library of cells provided for a particular project, etc. In many cases, the choices made by different design tools or methodologies to produce these different implementations may be arbitrary.

Moreover, it is common for a single implementation of a particular functional specification of a circuit to include, for a given embodiment, a large number of devices (e.g., millions of transistors). Accordingly, the sheer volume of this information makes it impractical to provide a full recitation of the low-level structure used to implement a single embodiment, let alone the vast array of equivalent possible implementations. For this reason, the present disclosure describes structure of circuits using the functional shorthand commonly employed in the industry.

What is claimed is:

1. An apparatus, comprising:
a plurality of memory cells configured to store respective bits of data;
a control circuit configured to:
receive a particular read access command that includes a particular address;
check an operating mode; and
in response to a determination that the operating mode is a destructive read mode:
sense a particular set of bits stored in corresponding memory cells of a particular subset of the plurality of memory cells identified by the particular address; and
abort, upon a completion of sensing the particular set of bits, a particular restore operation of the particular set of bits into the corresponding memory cells of the particular subset of the plurality of memory cells.

2. The apparatus of claim 1, wherein the control circuit is further configured, in response to a determination that the operating mode is a non-destructive read mode, to:
receive a different read access command that includes a different address; and
in response to a determination that the operating mode is a non-destructive read mode:
sense a different set of bits stored in corresponding memory cells of a different subset of the plurality of memory cells identified by the different address; and
perform, upon a completion of sensing the different set of bits, a restore operation of the different set of bits into the corresponding memory cells of the different subset of the plurality of memory cells.

3. The apparatus of claim 1, wherein the control circuit is further configured to:
receive a different read access command that includes a different address;
receive a read-mode signal; and
in response to a determination that the read-mode signal indicates the different read access command is destructive:
sense a different set of bits stored in corresponding memory cells of a different subset of the plurality of memory cells identified by the different address; and
abort, upon a completion of sensing the different set of bits, a different restore operation of the different set of bits into the corresponding memory cells of the different subset of the plurality of memory cells.

4. The apparatus of claim 1, further comprising a mode control register circuit, and wherein to check the operating mode, the control circuit is further configured to retrieve mode information stored in the mode control register circuit.

5. The apparatus of claim 4, wherein the control circuit is further configured to:
receive an update read-mode signal; and
modify contents of the mode control register circuit using the update read-mode signal.

6. The apparatus of claim 1, wherein a given memory cell of the plurality of memory cells includes at least one transistor and at least one capacitor.

7. A method, comprising:
receiving, by a memory circuit, a particular read access command that includes a particular address, wherein the memory circuit includes a plurality of memory cells;
checking, by the memory circuit, an operating mode;
in response to determining that the operating mode indicates a destructive read mode:
sensing, by the memory circuit, a particular set of bits stored in corresponding memory cells of a particular subset of the plurality of memory cells identified by the particular address; and
aborting, by the memory circuit upon completing the sensing, a restore operation of the particular set of bits into the corresponding memory cells of the particular subset of the plurality of memory cells.

8. The method of claim 7, further comprising:
receiving, by the memory circuit, a different read access command that includes a different address;
in response to determining that the operating mode indicates a non-destructive read mode:
sensing, by the memory circuit, a different set of bits stored in corresponding memory cells of a different subset of the plurality of memory cells identified by the different address; and
performing, by the memory circuit upon completing the sensing, a restore operation of the different set of bits into the corresponding memory cells of the different subset of the plurality of memory cells.

9. The method of claim 7, further comprising:
receiving, by the memory circuit, a different read access command that includes a different address;
receiving, by the memory circuit, a read-mode signal;
in response to determining that the read-mode signal indicates the destructive read mode:
sensing, by the memory circuit, a different set of bits stored in corresponding memory cells of a different subset of the plurality of memory cells identified by the different address; and
aborting, by the memory circuit upon completing the sensing, a different restore operation of the different set of bits into the corresponding memory cells of the different subset of the plurality of memory cells.

10. The method of claim 7, wherein the memory circuit includes a mode control register circuit, and wherein checking the operating mode includes retrieving, by the memory circuit, mode information stored in the mode control register circuit.

11. The method of claim 10, further comprising:
receiving, by the memory circuit, an update read-mode signal; and
storing, by the memory circuit using the update read-mode signal, a modified version of the mode information into the mode control register circuit.

12. The method of claim 10, further comprising, in response to initializing a computer system that includes the memory circuit, storing initial mode information in the mode control register circuit.

13. The method of claim 7, further comprising halting, by the memory circuit, at least one refresh operation in response to determining that the operating mode indicates the destructive read mode.

14. A system, comprising:
a memory circuit including a plurality of memory cells configured to store respective bits; and
a logic circuit configured to send a plurality of read access commands to the memory circuit; and
wherein the memory circuit is configured to:
check an operating mode;
in response to a determination that the operating mode indicates a destructive read mode:
sense a particular set of bits stored in corresponding memory cells of a particular subset of the plurality of memory cells identified by a particular address included in a particular read access command of the plurality of read access commands; and
abort, upon completion of sensing the particular set of bits, a particular restore operation of the particular set of bits into the corresponding memory cells of the particular subset of the plurality of memory cells.

15. The system of claim 14, wherein the memory circuit is further configured, in response to a determination that the operating mode indicates a non-destructive read mode, to:
sense a different set of bits stored in corresponding memory cells of a different subset of the plurality of memory cells identified by a different address included in a different read access command of the plurality of read access commands; and
perform a restore operation of the different set of bits into the corresponding memory cells of the different subset of the plurality of memory cells.

16. The system of claim 14, wherein the logic circuit is further configured to send a read-mode signal in conjunction with a different read access command of the plurality of read access commands, and wherein the memory circuit is further configured to:
in response to a determination that the read-mode signal indicates the destructive read mode:
sense a different set of bits stored in corresponding memory cells of a different subset of the plurality of memory cells identified by a different address included in the different read access command; and
abort, upon a completion of sensing the different set of bits, a different restore operation of the different set of bits into the corresponding memory cells of the different subset of the plurality of memory cells.

17. The system of claim 14, wherein the logic circuit includes a processor circuit.

18. The system of claim 14, wherein the logic circuit includes an array of processor circuits.

19. The system of claim 14, wherein the logic circuit is further configured to send an update read-mode signal to the memory circuit, and wherein the memory circuit is further configured to modify the operating mode using the update read-mode signal.

20. The system of claim 14, wherein the plurality of memory cells includes a given memory cell that includes at least one transistor and at least one capacitor.
